(19) United States
(12) Patent Application Publication
(10) Pub. No.: US 2026/0136956 A1
(43) Pub. Date: May 14, 2026

(54) WIRING SUBSTRATE AND SEMICONDUCTOR DEVICE

(71) Applicant: SHINKO ELECTRIC INDUSTRIES CO., LTD., Nagano (JP)

(72) Inventor: Michio HORIUCHI, Nagano (JP)

(21) Appl. No.: 19/378,702

(22) Filed: Nov. 4, 2025

(30) Foreign Application Priority Data
Nov. 8, 2024 (JP) 2024-196009

(51) Int. Cl. H01L 23/538; H01L 21/48; H01L 23/00; H01L 23/15; H01L 23/498; H01L 25/065

(52) U.S. Cl. CPC H10W 70/611; H10W 70/05; H10W 70/685; H10W 90/00; H10W 70/66; H10W 70/692; H10W 90/724

(57) ABSTRACT

A wiring substrate includes a ceramic layer, a first wiring layer in the ceramic layer, a glass layer on the ceramic layer, and a second wiring layer on a surface of the glass layer on the opposite side from the first wiring layer. The glass layer is free of voids. The second wiring layer is electrically connected to the first wiring layer.

### CROSS-REFERENCE TO RELATED APPLICATION

This application is based upon and claims priority to Japanese Patent Application No. 2024-196009, filed on Nov. 8, 2024, the entire contents of which are incorporated herein by reference.

### FIELD

A certain aspect of the embodiments discussed herein is related to wiring substrates and semiconductor devices.

### BACKGROUND

Wiring is undergoing miniaturization and increased density with advancement in the performance and high-density packing of semiconductor devices. According to related-art wiring substrates using organic materials, it is difficult to form miniaturized wiring with high density due to expansion or contraction during a process. Furthermore, reliability problems due to moisture absorption have become more serious for wiring substrates using organic materials with advancement in the miniaturization of wiring.

To address these problems, the method of combining an inorganic material such as silicon with wiring substrates using organic materials or the method of forming miniaturized wiring with high density using silicon alone as a substrate has also been employed. Silicon, however, has a problem in high material cost and high processing cost due to difficulties in forming vertical through conductors in the substrate.

Compared with silicon, glass is inexpensive and is easy to form miniaturized wiring on with high density because of high surface smoothness and flatness and few defects. Furthermore, because glass itself is insulating material, there is no need to form an insulating layer, and it is relatively easy to form vertical through conductors in the substrate. Therefore, in recent years, the development of wiring substrates for semiconductor mounting using glass as a substrate has been progressing. (See, for example, Japanese Laid-open Patent Publication No. 2023-145618.)

### SUMMARY

According to an aspect, a wiring substrate includes a ceramic layer, a first wiring layer in the ceramic layer, a glass layer on the ceramic layer, and a second wiring layer on a surface of the glass layer on the opposite side from the first wiring layer. The glass layer is free of voids. The second wiring layer is electrically connected to the first wiring layer.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a cross-sectional view of a wiring substrate according to a first embodiment;

FIG. 2 is a cross-sectional scanning electron microscope (SEM) image of the interface between a ceramic layer and a glass layer;

FIGS. 3A through 3F are diagrams illustrating a process of manufacturing a wiring substrate according to the first embodiment;

FIG. 4 is a cross-sectional view of a wiring substrate according to a first variation of the first embodiment;

FIG. 5 is a cross-sectional view of a wiring substrate according to a second variation of the first embodiment;

FIG. 6 is a cross-sectional view of a wiring substrate according to a third variation of the first embodiment;

FIG. 7 is a cross-sectional view of a wiring substrate according to a fourth variation of the first embodiment; and

FIG. 8 is a cross-sectional view of a semiconductor device according to a second embodiment.

### DESCRIPTION OF EMBODIMENTS

Glass, however, has low thermal conductivity. Therefore, wiring substrates using glass as a substrate are at a disadvantage in terms of heat dissipation, which is required for high-density wiring.

According to an aspect, both high-density wiring and heat dissipation are achieved in wiring substrates including a glass layer.

Embodiments of the present invention are explained with reference to the accompanying drawings. In the following description, the same elements are referred to using the same reference numerals, and duplicate description thereof may be omitted.

### a First Embodiment

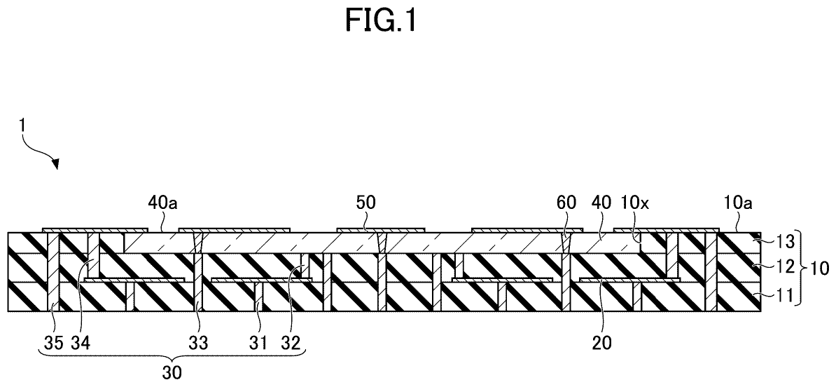

The structure of a wiring substrate according to a first embodiment is described. FIG. 1 is a cross-sectional view of a wiring substrate according to the first embodiment. As illustrated in FIG. 1, a wiring substrate 1 includes a ceramic layer 10, a first wiring layer 20, first via wiring 30, a glass layer 40, a second wiring layer 50, and second via wiring 60.

The ceramic layer 10 has a multilayer structure composed of a ceramic substrate 11, a ceramic substrate 12, and a ceramic substrate 13 that are successively stacked. The number of ceramic substrates stacked in layers is not limited to the example of FIG. 1. The ceramic substrates 11 through 13 constituting the ceramic layer 10 are preferably made of one of an alumina (aluminum oxide) ceramic, a mullite ceramic, and an aluminum nitride ceramic.

The aluminum ceramic has higher mechanical strength than the glass layer 40. Furthermore, the alumina ceramic is higher in thermal conductivity than the glass layer 40 and has a thermal conductivity of approximately 15 W/mK to approximately 20 W/mK. The alumina ceramic has a coefficient of thermal expansion of approximately 7×10⁻⁶/°C. The alumina ceramic may be fired at approximately 1500° C. to approximately 1600° C. in the atmosphere or in a non-oxidizing atmosphere.

The mullite ceramic has a thermal conductivity of approximately 7 W/mK, which is lower than that of the alumina ceramic. The mullite ceramic, however, has the advantage of having a coefficient of thermal expansion of approximately 4.5×10^{Δ6}/°C., which is close to that of silicon, which is a semiconductor device material. The mullite ceramic may be fired at approximately 1500° C. to approximately 1600° C. in the atmosphere or in a non-oxidizing atmosphere.

The aluminum nitride ceramic has a thermal conductivity of 140 W/mK to 240 W/mK, which is substantially higher than that of the alumina ceramic and serves as an advantage in improving heat dissipation. Furthermore, the aluminum nitride ceramic has the advantage of having a coefficient of thermal expansion of approximately 4.5×10⁻⁶/°C., which is close to that of silicon, which is a semiconductor device material. The aluminum nitride ceramic may be fired at approximately 1800° C. to approximately 1900° C. in a nitrogen atmosphere. The firing may be carried out in an atmosphere of non-oxidizing gases such as argon instead of a nitrogen atmosphere.

The first wiring layer 20 is provided in the ceramic layer 10. According to the example of FIG. 1, the first wiring layer 20 is buried in the ceramic layer 10. Specifically, the first wiring layer 20 is placed on the upper surface of the ceramic substrate 11 and is covered with the ceramic substrate 12. That is, the first wiring layer 20 is at the interface between the ceramic substrates 11 and 12. The first wiring layer 20 may include multiple layers. For example, the first wiring layer 20 may be provided on the upper surface of the ceramic substrate 11 and on the upper surface of the ceramic substrate 12. The thickness of the first wiring layer 20 may be, for example, 5 μm or more and 40 μm or less.

The first via wiring 30 is provided in the ceramic layer 10. The first via wiring 30 may include through conductors 31 piercing through the ceramic substrate 11, through conductors 32 piercing through the ceramic substrate 12, through conductors 33 piercing through the ceramic substrates 11 and 12, through conductors 34 piercing through the ceramic substrates 12 and 13, and through conductors 35 piercing through the ceramic substrates 11, 12 and 13. The first via wiring 30 does not have to include all of these through conductors 31 through 35. The first via wiring 30 may include only through conductors piercing through the ceramic substrate 13.

The first wiring layer 20 and the first via wiring 30 may include, for example, one of tungsten, molybdenum, copper, and aluminum as their main component. Tungsten, molybdenum or copper conductors may be fired and formed simultaneously with the alumina ceramic, the mullite ceramic, or the aluminum nitride ceramic in a non-oxidizing atmosphere. Copper melts during firing. Therefore, copper has to be prevented from being exposed on the surface of a ceramic substrate during firing. Aluminum conductors may be fired and formed simultaneously with the aluminum ceramic or the mullite ceramic in a non-oxidizing atmosphere or in an atmospheric environment. Aluminum melts during firing. Therefore, aluminum has to be prevented from being exposed on the surface of a ceramic substrate during firing. Copper and aluminum, which require a lot of effort for protection of molten metal, have the advantage of low resistance.

The glass layer 40 is placed in contact with the ceramic layer 10. The thickness of the glass layer 40 is, for example, 20 μm or more and 200 μm or less. When the thickness of the glass layer 40 is within this range, it is easy to form the second via wiring 60. Furthermore, this range of the thickness of the glass layer 40 facilitates impedance matching.

The glass layer 40 is amorphous and may include silicon oxide as a main component. The glass layer 40 is free of voids. In this specification, the void is defined as a gap of 0.5 μm or more in size, and a gap of less than 0.5 μm in size is not considered the void. Voids are present in the ceramic layer 10.

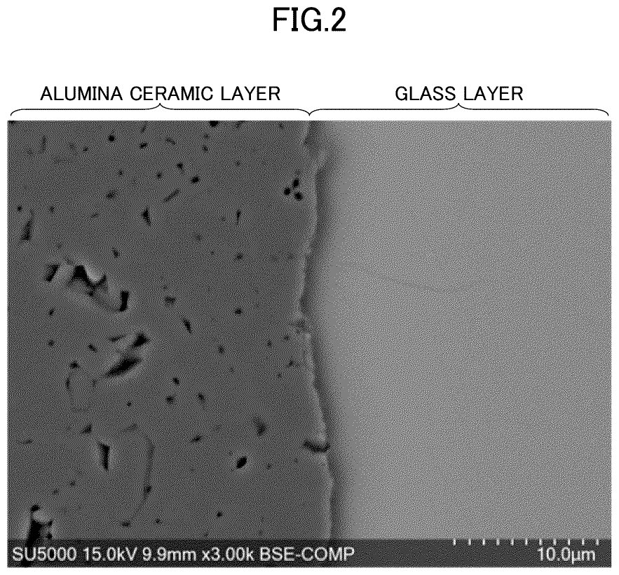

FIG. 2 is a cross-sectional scanning electron microscope (SEM) image of the interface between a ceramic layer and a glass layer. Here, by way of example, a cross-sectional SEM image in the case of forming a glass layer on a high-purity alumina ceramic layer free of silicon is presented. As illustrated in FIG. 2, voids of approximately 1 μm to approximately 5 μm can be observed in the alumina ceramic layer, while no voids can be observed in the glass layer.

Because of such a difference with respect to the presence or absence of voids, it is difficult to form miniaturized wiring in or on the ceramic layer, while it is possible to form miniaturized wiring in or on the glass layer. For example, it is possible to form miniaturized wiring of a line/space of 2 μm/2 μm or less in or on the glass layer. In contrast, in the case of forming miniaturized wiring in or on the ceramic layer, because of the possible occurrence of disconnection or partial thinning of wiring due to the presence of voids, the line/space of the wiring formed in or on the ceramic layer is preferably 30 μm/30 μm or more.

According to the example of FIG. 1, the glass layer 40 is placed in a recess 10x provided in an upper surface 10a of the ceramic layer 10. The number of recesses 10x provided in the single ceramic layer 10, which is one according to the example of FIG. 1, does not have to be one, and may be any number greater than or equal to one. In the case of providing more than one recess 10x, the glass layer 40 is placed apart in each recess 10x. An upper surface 40a of the glass layer 40 is preferably flush with the upper surface 10a of the ceramic layer 10.

The second wiring layer 50 is provided on the upper surface 40a of the glass layer 40. The second wiring layer 50 is electrically connected to the first wiring layer 20. According to the example of FIG. 1, part of the second wiring layer 50 extends from the upper surface 40a of the glass layer 40 to the upper surface 10a of the ceramic layer 10 to be electrically connected to the first wiring layer 20 via the through conductors 34 constituting the first via wiring 30 provided in the ceramic layer 10.

The thickness of the second wiring layer 50 may be, for example, 1 μm or more and 5 μm or less. The line/space of the second wiring layer 50 may be, for example, 2 μm/2 μm or less. As noted above, however, it is not preferable to form miniaturized wiring on the upper surface 10a of the ceramic layer 10. Therefore, the line/space of the part of the second wiring layer 50 extending from the upper surface 40a of the glass layer 40 to the upper surface 10a of the ceramic layer 10 preferably switches to 30 μm/30 μm or more on the upper surface 10a of the ceramic layer 10.

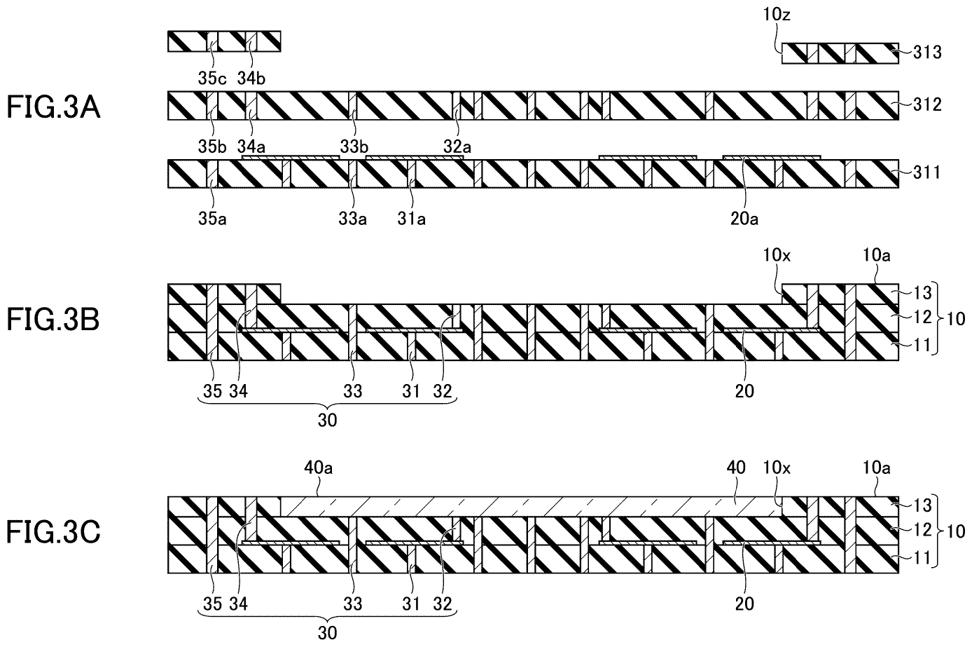

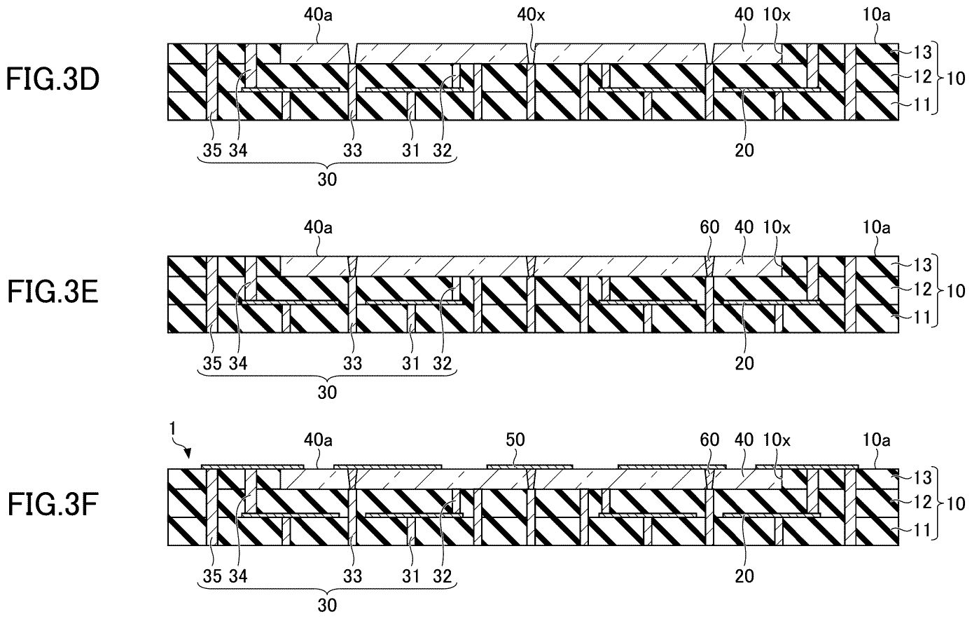

Next, a method of manufacturing a wiring substrate according to the first embodiment is described. FIGS. 3A through 3F are diagrams illustrating a process of manufacturing a wiring substrate according to the first embodiment. A process of manufacturing the wiring substrate 1 is described with reference to FIGS. 3A through 3F.

First, in the processes illustrated in FIGS. 3A and 3B, the ceramic layer 10 in which the first wiring layer 20 and the first via wiring 30 are provided is formed. Specifically, in the process illustrated in FIG. 3A, green sheets 311, 312 and 313 are prepared, and through holes are formed where through conductors are to be formed. An opening 10z is provided in the green sheet 313. The through holes in the green sheets 311, 312 and 313 may be so formed as to be approximately 80 μm to approximately 400 μm in diameter after firing, for example. The green sheets 311, 312 and 313 are preferably of an alumina ceramic, a mullite ceramic, or an aluminum nitride ceramic. The green sheets 311, 312 and 313 are densified through sintering to become the ceramic substrates 11, 12 and 13, respectively, as illustrated in FIG. 1.

Next, metal paste 20a to become the first wiring layer 20 after firing is formed on the upper surface of the green sheet 311. Furthermore, metal paste 31a to become the through conductors 31 after firing, metal paste 33a to become part of the through conductors 33 after firing, and metal paste 35a to become part of the through conductors 35 after firing are formed in the through holes formed in the green sheet 311. Furthermore, metal paste 32a to become the through conductors 32 after firing, metal paste 33b to become part of the through conductors 33 after firing, metal paste 34a to become part of the through conductors 34 after firing, and metal paste 35b to become part of the through conductors 35 after firing are formed in the through holes formed in the green sheet 312. Furthermore, metal paste 34b to become part of the through conductors 34 after firing and metal paste 35c to become part of the through conductors 35 after firing are formed in the through holes formed in the green sheet 313. The metal paste may include, for example, tungsten, molybdenum, copper or aluminum as its main component. The metal paste may be formed by, for example, screen printing.

Next, in the process illustrated in FIG. 3B, a laminate is formed by sequentially stacking the green sheets 311, 312 and 313 formed in the process illustrated in FIG. 3A, and the green sheets 311 through 313 and the metal paste are simultaneously fired. For example, when the green sheets 311 through 313 are of an alumina ceramic or a mullite ceramic and the metal paste is tungsten, molybdenum or copper paste, firing is performed at approximately 1500° C. to approximately 1600° C. in a non-oxidizing atmosphere.

As a result, the green sheets 311, 312 and 313 become the ceramic substrates 11, 12 and 13, respectively, which are integrated into the ceramic layer 10 as a one-piece structure. The opening 10z becomes the recess 10x with the bottom being formed by the upper surface of the ceramic substrate 12. Furthermore, the metal paste 20a becomes the first wiring layer 20. The metal paste 31a becomes the through conductors 31. The metal paste 32a becomes the through conductors 32. The metal paste 33a and the metal paste 33b are integrated into the through conductors 33. The metal paste 34a and the metal paste 34b are integrated into the through conductors 34. The metal paste 35a, the metal paste 35b, and the metal paste 35c are integrated into the through conductors 35. As a result, the first via wiring 30 including the through conductors 31, the through conductors 32, the through conductors 33, the through conductors 34, and the through conductors 35 is formed.

After the ceramic layer 10 is formed, it is preferable to polish the upper surface 10a of the ceramic layer 10 into a flat surface.

Next, in the process illustrated in FIG. 3C, the glass layer 40 free of voids is formed in contact with the ceramic layer 10. Specifically, for example, paste formed of glass powder is applied or glass preform is placed in the recess 10x of the ceramic layer 10, and heat treatment is thereafter performed in a vacuum or a non-oxidizing atmosphere to form the glass layer 40. According to these methods, the glass layer 40 free of voids can be formed. The temperature of the heat treatment is such that the paste of glass powder or the glass preform melts but the first via wiring 30 exposed from the ceramic layer 10 does not melt. For example, when the first via wiring 30 is tungsten, molybdenum or copper, the temperature of the heat treatment may be 500° C. or higher and 1000° C. or lower. Furthermore, when the first via wiring 30 is aluminum, the temperature of the heat treatment may be 500° C. or higher and 600° C. or lower.

It is preferable to polish the upper surface 40a of the glass layer 40 to a mirror finish after forming the glass layer 40. At this point, it is preferable to also polish the upper surface 10a of the ceramic layer 10 so that the upper surface 40a of the glass layer 40 and the upper surface 10a of the ceramic layer 10 form a single plane.

Next, in the process illustrated in FIG. 3D, through holes 40x to expose the upper surface of the first via wiring 30 are formed in the glass layer 40. Various methods that have been put into practical use may be employed to form the through holes 40x. For example, one of such methods is to optically modify and thereafter chemically etch part of the glass layer 40 where the through holes 40x are to be formed. Furthermore, laser light may be emitted onto the glass layer 40 to form the through holes 40x.

Next, in the process illustrated in FIG. 3E, the second via wiring 60 to fill in the through holes 40x is formed. The second via wiring 60 may be formed by, for example, a wet plating process using copper.

Next, in the process illustrated in FIG. 3F, the second wiring layer 50 to be electrically connected to the first wiring layer 20 is formed on the upper surface 40a of the glass layer 40. The second wiring layer 50 may be formed by, for example, sputtering or plating, using copper. The line/space of the second wiring layer 50 may be, for example, 2 μm/2 μm or less. In the case of forming the second wiring layer 50 such that the second wiring layer 50 extends from the upper surface 40a of the glass layer 40 to the upper surface 10a of the ceramic layer 10, the line/space of the second wiring layer 50 preferably switches to 30 μm/30 μm or more on the upper surface 10a of the ceramic layer 10. The second wiring layer 50 and the second via wiring 60 may be formed as a one-piece structure by plating or the like. In this manner, the wiring substrate 1 is completed.

The structure illustrated in FIG. 3F corresponds to a single wiring substrate 1. In the manufacturing process, two or more of such structures are simultaneously manufactured and are eventually cut into individual wiring substrates 1. Substrate materials formed only of a glass layer have a problem in that cracks start from a side surface to develop in a plane direction in final cutting. Cracks occur because a tensile stress caused by the formation of a conductor layer on the surface of the substrate is likely to focus on the side surface during cutting. It is known that such a stress is likely to develop cracks in glass material. In contrast, in ceramic material, cracks are unlikely to develop because of grain boundaries and voids because ceramic material has relatively high mechanical strength and is polycrystalline material. Therefore, the structure illustrated in FIG. 3F, whose cut surface is not glass but ceramic, produces a crack prevention effect during cutting.

Thus, according to the wiring substrate 1, the glass layer 40 free of voids is placed in contact with the ceramic layer 10. Use of the void-free glass layer 40 makes it possible to increase the density of the second wiring layer 50 formed on the upper surface 40a of the glass layer 40. Furthermore, while the glass layer 40 is low in thermal conductivity, the glass layer 40 is placed in contact with the ceramic layer 10 having high mechanical strength, so that high mechanical strength can be maintained by the ceramic layer 10. Accordingly, it is possible to reduce the thickness of the glass layer 40. As a result, the thermal resistance of the glass layer 40 is reduced by reduction in its thickness, and heat is more likely to be dissipated and removed through the ceramic layer 10, which has good thermal conductivity. Therefore, it is possible to improve the heat dissipation properties of the wiring substrate 1.

Furthermore, reduction in the thickness of the glass layer 40 makes it possible to reduce the length of the second via wiring 60. That is, because there is no need to form the second via wiring 60 with a high aspect ratio, it is possible to reduce the diameter and pitch of the second via wiring 60. This makes it possible to increase the density of the second wiring layer 50.

### First Variation of First Embodiment

According to a first variation of the first embodiment, a third wiring layer is formed at the interface between the glass layer and the ceramic layer.

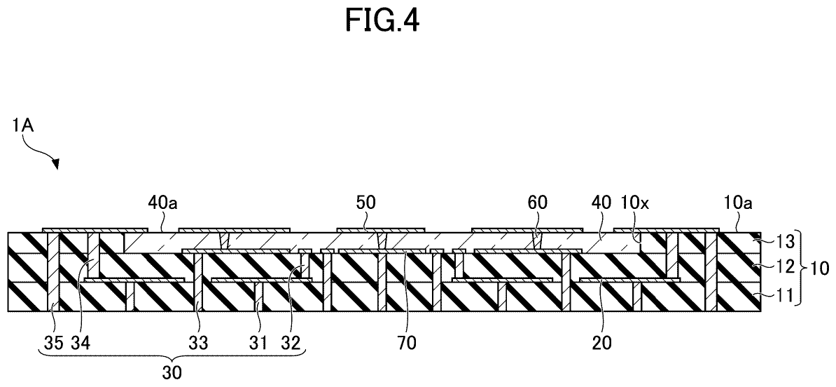

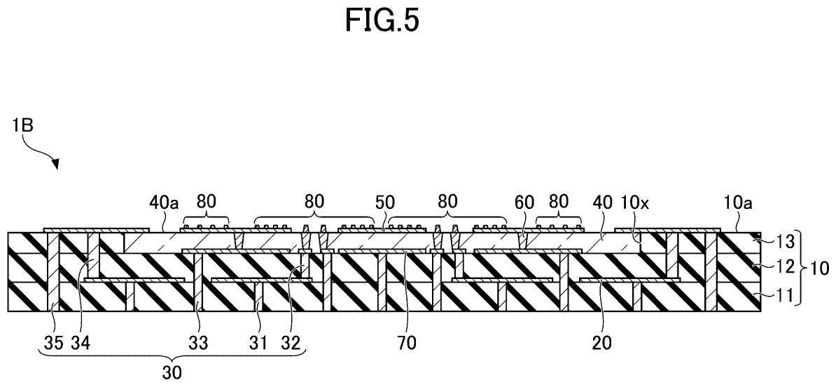

FIG. 4 is a cross-sectional view of a wiring substrate according to the first variation of the first embodiment. As illustrated in FIG. 4, a wiring substrate 1A is different from the wiring substrate 1 in that a third wiring layer 70 is formed at the interface between the glass layer 40 and the ceramic layer 10.

The third wiring layer 70 is placed on the upper surface of the ceramic substrate 12, which defines the bottom of the recess 10x, and is covered with the glass layer 40. The third wiring layer 70 is electrically connected to the first wiring layer 20 via the first via wiring 30. The second wiring layer 50 is electrically connected to the third wiring layer 70 via the second via wiring 60 provided in the glass layer 40.

The third wiring layer 70 is formed on the upper surface of the ceramic substrate 12, which defines the bottom of the recess 10x, before the formation of the glass layer 40, for example. The third wiring layer 70 may be formed by, for example, firing the same metal paste as the metal paste 20a simultaneously with the metal paste 20a. The third wiring layer 70 may alternatively be formed by placing metal paste on the upper surface of the ceramic substrate 12, which defines the bottom of the recess 10x, after firing the ceramic layer 10, and then performing secondary firing. As yet another alternative, the third wiring layer 70 may be formed on the upper surface of the ceramic substrate 12, which defines the bottom of the recess 10x, by wet plating or sputtering after firing the ceramic layer 10.

Thus, by placing the first wiring layer 20 inside the ceramic layer 10, placing the second wiring layer 50 on the upper surface 40a of the glass layer 40, and placing the third wiring layer 70 at the interface between the ceramic layer 10 and the glass layer 40, it is possible to increase the wiring density of the wiring substrate 1 to improve functionality.

### Second Variation of First Embodiment

According to a second variation of the first embodiment, connections are provided over a surface of the glass layer.

FIG. 5 is a cross-sectional view of a wiring substrate according to the second variation of the first embodiment. As illustrated in FIG. 5, a wiring substrate 1B is different from the wiring substrate 1 in that multiple connections 80 are provided over the upper surface 40a of the glass layer 40.

Each of the connections 80 is a cluster of protruding electrodes. The protruding electrodes may be formed of, for example, copper. In order to mount two or more semiconductor chips, the wiring substrate 1B includes two or more (four in the example of FIG. 5) connections 80. The connections 80 are interconnected by the second wiring layer 50. This configuration facilitates connecting adjacent semiconductor chips when a semiconductor chip is mounted on each of the connections 80.

### Third Variation of First Embodiment

According to a third variation of the first embodiment, the glass layer is placed on the entirety of a surface of the ceramic layer.

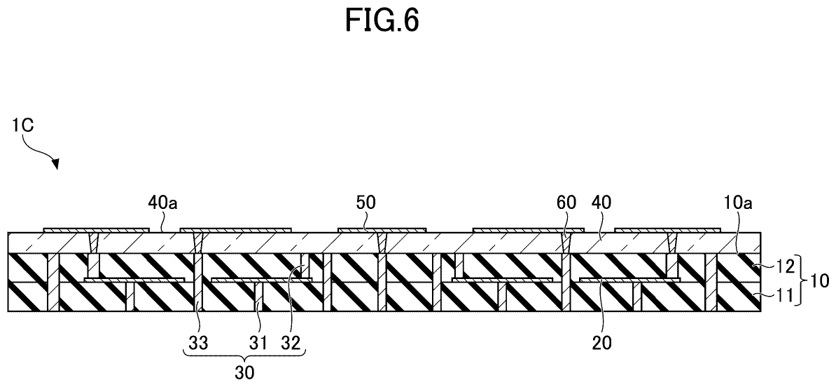

FIG. 6 is a cross-sectional view of a wiring substrate according to the third variation of the first embodiment. As illustrated in FIG. 6, a wiring substrate 1C is different from the wiring substrate 1 in that the glass layer 40 is placed on the upper surface 10a of the ceramic layer 10 and covers the entirety of the upper surface 10a of the ceramic layer 10.

According to the wiring substrate 1C, the ceramic layer 10 includes the ceramic substrates 11 and 12 but does not include the ceramic substrate 13. Therefore, the recess 10x is not provided in the ceramic layer 10 in the wiring substrate 1C.

According to the wiring substrate 1C, the second wiring layer 50 provided on the upper surface 40a of the glass layer 40 is electrically connected to the first wiring layer 20 via the second via wiring 60 provided in the glass layer 40 and the first via wiring 30 provided in the ceramic layer 10.

Thus, the glass layer 40 may be either placed in the recess 10x provided in the ceramic layer 10 or placed on the upper surface 10a of the ceramic layer 10 in such a manner as to cover the entirety of the upper surface 10a of the ceramic layer 10.

### Fourth Variation of First Embodiment

According to a fourth variation of the first embodiment, a wiring structure that reduces the electromagnetic interference between signal traces is provided.

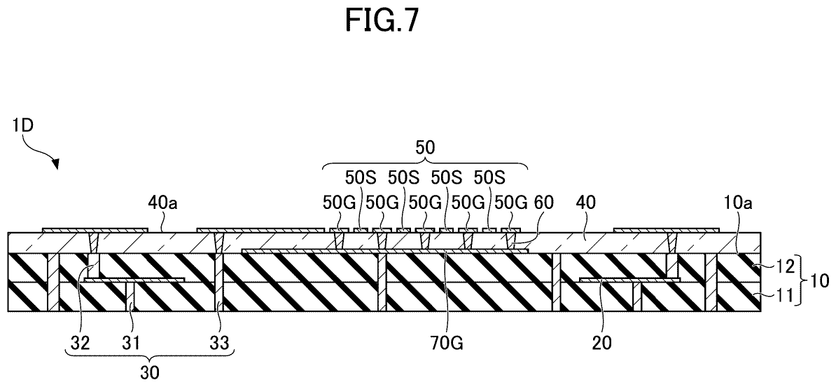

FIG. 7 is a cross-sectional view of a wiring substrate according to the fourth variation of the first embodiment. As illustrated in FIG. 7, a wiring substrate 1D is different from the wiring substrate 1C in that the second wiring layer 50 includes ground traces 50G and signal traces 50S.

The ground traces 50G are provided one on each side of each signal trace 50S, being spaced apart from the signal trace 50S. The ground traces 50G are connected to a third wiring layer 70G via the second via wiring 60. By grounding the third wiring layer 70G to the ground potential via the first via wiring 30, all of the ground traces 50G are grounded to the ground potential. This makes it possible to reduce the electromagnetic interference between the signal traces 50S. It is also possible to provide the ground traces 50G and the signal traces 50S on the upper surface 40a of the glass layer 40 placed in the recess 10x.

### Second Embodiment

A second embodiment relates to a semiconductor device having a semiconductor chip mounted on a wiring substrate.

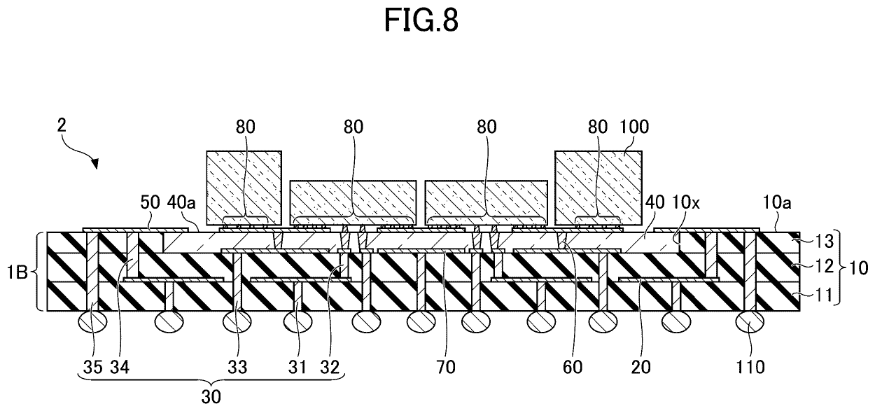

FIG. 8 is a cross-sectional view of a semiconductor device according to the second embodiment. As illustrated in FIG. 8, a semiconductor device 2 includes the wiring substrate 1B and multiple semiconductor chips 100 mounted on the wiring substrate 1B. Each semiconductor chip 100 is electrically connected to a corresponding one of the connections 80 of the wiring substrate 1B. As described above, the connections 80 are interconnected by the second wiring layer 50. Therefore, it is possible to easily connect the adjacent semiconductor chips 100 with each other with a short path.

External connection terminals 110 such as solder balls may be provided on the lower surface of the first via wiring 30 on an as-needed basis.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

Various aspects of the subject-matter described herein may be set out non-exhaustively in the following numbered clause:
1. A method of manufacturing a wiring substrate, the method including:
forming a ceramic layer in which a first wiring layer is provided;
forming a glass layer in contact with the ceramic layer, the glass layer being free of voids; and
forming a second wiring layer on a surface of the glass layer on an opposite side from the first wiring layer such that the second wiring layer is electrically connected to the first wiring layer,
wherein the glass layer is formed by applying paste formed of glass powder or placing glass preform and thereafter performing heat treatment in a vacuum or a non-oxidizing atmosphere.

What is claimed is:

1. A wiring substrate comprising:
a ceramic layer;
a first wiring layer in the ceramic layer;
a glass layer on the ceramic layer, the glass layer being free of voids; and
a second wiring layer on a surface of the glass layer on an opposite side from the first wiring layer, the second wiring layer being electrically connected to the first wiring layer.

2. The wiring substrate as claimed in claim 1, wherein the glass layer is in one or more recesses in a surface of the ceramic layer.

3. The wiring substrate as claimed in claim 2, wherein the surface of the glass layer and the surface of the ceramic layer constitute a single plane.

4. The wiring substrate as claimed in claim 3, further comprising:
first via wiring in the ceramic layer,
wherein the second wiring layer extends from the surface of the glass layer to the surface of the ceramic layer and is electrically connected to the first wiring layer via the first via wiring.

5. The wiring substrate as claimed in claim 2, wherein
the ceramic layer includes a first ceramic substrate, a second ceramic substrate, and a third ceramic substrate sequentially stacked in layers,
the first wiring layer is at an interface between the first ceramic substrate and the second ceramic substrate, and
the glass layer is in one or more openings formed in the third ceramic substrate.

6. The wiring substrate as claimed in claim 1, wherein the glass layer is on a surface of the ceramic layer and covers an entirety of the surface of the ceramic layer.

7. The wiring substrate as claimed in claim 1, further comprising:
a third wiring layer at an interface between the glass layer and the ceramic layer.

8. The wiring substrate as claimed in claim 1, wherein the glass layer includes silicon oxide as a main component.

9. The wiring substrate as claimed in claim 1, further comprising:
a plurality of connections for mounting two or more semiconductor chips over the surface of the glass layer,
wherein the plurality of connections are interconnected by the second wiring layer.

10. The wiring substrate as claimed in claim 9, wherein each of the plurality of connections is a cluster of protruding electrodes.

11. The wiring substrate as claimed in claim 1, wherein
the second wiring layer includes a plurality of ground traces and a plurality of signal traces, and
the plurality of ground traces are provided one on each side of each of the plurality of signal traces, being spaced apart from said each of the plurality of signal traces.

12. The wiring substrate as claimed in claim 1, wherein the ceramic layer is formed of an alumina ceramic, a mullite ceramic, or an aluminum nitride ceramic.

13. The wiring substrate as claimed in claim 1, wherein the first wiring layer includes tungsten, molybdenum, copper, or aluminum as a main component.

14. The wiring substrate as claimed in claim 1, wherein the glass layer has a thickness of 20 μm or more and 200 μm or less.

15. A semiconductor device comprising:
the wiring substrate as set forth in claim 9; and
a plurality of semiconductor chips mounted on the wiring substrate,
wherein each of the plurality of semiconductor chips is electrically connected to a corresponding one of the plurality of connections.
